(19) United States
(12) Patent Application Publication
(10) Pub. No.: US 2013/0168796 A1
(43) Pub. Date: Jul. 4, 2013

(54) PHOTODIODE ARRAYS AND METHODS OF FABRICATION

(71) Applicants: Abdelaziz Ikhlef, Hartland, WI (US); Wen Li, Clifton Park, NY (US)

(72) Inventors: Abdelaziz Ikhlef, Hartland, WI (US); Wen Li, Clifton Park, NY (US)

(73) Assignee: GENERAL ELECTRIC COMPANY, Schenectady, NY (US)

(21) Appl. No.: 13/343,146

(22) Filed: Jan. 4, 2012

(51) Int. Cl. H01L 27/146; H01L 31/18

(52) U.S. Cl. 257/448; 438/73; 257/E31.124; 257/E27.133

(57) ABSTRACT

Photodiode arrays and methods of fabrication are provided. One photodiode array includes a silicon wafer having a first surface and an opposite second surface. The photodiode array also includes a plurality of refilled conductive vias through the silicon wafer, wherein the refilled conductive vias have a doping type different than the doping type of the substrate, and an interface between the refilled conductive vias and the substrate form diode junctions. The photodiode array further includes a patterned doped layer on the first surface overlapping the refilled conductive vias, wherein the patterned doped layer defines an array of photodiodes.

### BACKGROUND OF THE INVENTION

Photodiodes are used in many different applications. For example, photodiodes may be used as part of detectors in imaging systems, such as x-ray imaging systems. In these x-ray imaging systems, x-rays produced by a source travel through an object being imaged and are detected by the detectors. In response thereto, the detectors (that include photodiodes) produce digital signals that represent the sensed energy used for subsequent processing and image reconstruction.

In known photodiode fabrication using a semiconductor wafer, a through-silicon-via process may be used to form a conductive via through the wafer. The conductive via then may be used to electrically connect diode junctions on one surface of the wafer with electronics or other electrical connections on an opposite surface of the wafer. In the through-silicon-via process, a dielectric layer is grown or deposited as isolation between a conductive via refill and the wafer substrate. The growth or deposition of the dielectric layer is a challenging process. In particular, to control the coupling capacitance between the via refill and the substrate, a thicker dielectric layer is used that adds complexity and cost to the deposition process.

Thus, known fabrication processes for forming imaging devices with conductive through-silicon-via structures for particular applications, such as detectors for imaging systems, use a through-silicon-via process with dielectric layer growth or deposition step that adds complexity and cost to the overall process.

### BRIEF DESCRIPTION OF THE INVENTION

In one embodiment, a photodiode array is provided that includes a silicon wafer having a first surface and an opposite second surface. The photodiode array also includes a plurality of refilled conductive vias through the silicon wafer, wherein the refilled conductive vias have a doping type different than the doping type of the substrate, and an interface between the refilled conductive vias and the substrate form diode junctions. The photodiode array further includes a pixelated photodiode array formed on the first surface with a pattern matching the refilled conductive vias. Each photodiode pixel is electrically connected to the conductive refill of a through-silicon-via defining a signal path to the second surface.

In another embodiment, a detector is provided that includes a silicon wafer having a first surface and an opposite second surface and a plurality of refilled conductive vias through the silicon wafer without a dielectric layer. The refilled conductive vias have a doping type different than the doping type of the substrate, and an interface between the refilled conductive vias and the substrate form diode junctions. The detector also includes a plurality of photodiodes formed at the first surface and interconnects formed on the opposite second surface by metalizations, wherein the plurality of photodiodes and the interconnects are electrically connected by the plurality of refilled conductive vias.

In yet another embodiment, a method for fabricating a photodiode array is provided. The method includes forming vias through a silicon wafer, refilling the vias with a doped silicon without a dielectric layer and forming a photodiode array on one surface of the silicon wafer. The method also includes using a doping type for the refill of the vias that is different from the substrate, wherein diode junctions are formed at an interface between the vias and the substrate.

### BRIEF DESCRIPTION OF THE DRAWINGS

FIG. 1 is a simplified schematic block diagram of an exemplary embodiment of an imaging system.

FIGS. 2-4 are diagrams illustrating a process for fabricating a photodiode array in accordance with various embodiments.

FIG. 5 is a flowchart of a method for forming a photodiode array in accordance with various embodiments.

FIG. 6 is a perspective view of a detector module formed in accordance with an embodiment.

FIG. 7 is a pictorial drawing of an exemplary embodiment of an imaging system in which a detector module having a photodiode array of various embodiments may be implemented.

FIG. 8 is a schematic block diagram of the imaging system shown in FIG. 7.

### DETAILED DESCRIPTION OF THE INVENTION

The following detailed description of certain embodiments will be better understood when read in conjunction with the appended drawings. To the extent that the figures illustrate diagrams of the functional blocks of various embodiments, the functional blocks are not necessarily indicative of the division between hardware circuitry. Thus, for example, one or more of the functional blocks (e.g., processors or memories) may be implemented in a single piece of hardware (e.g., a general purpose signal processor or random access memory, hard disk, or the like) or multiple pieces of hardware. Similarly, the programs may be stand alone programs, may be incorporated as subroutines in an operating system, may be functions in an installed software package, and the like. It should be understood that the various embodiments are not limited to the arrangements and instrumentality shown in the drawings.

As used herein, an element or step recited in the singular and proceeded with the word “a” or “an” should be understood as not excluding plural of said elements or steps, unless such exclusion is explicitly stated. Furthermore, references to “one embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

Also as used herein, the term “reconstructing” or “rendering” an image or data set is not intended to exclude embodiments in which data representing an image is generated, but a viewable image is not. Therefore, as used herein the term “image” broadly refers to both viewable images and data representing a viewable image. However, some embodiments generate, or are configured to generate, at least one viewable image. In an exemplary embodiment, the “object” being imaged is a human individual. However, the object may alternatively be of another living creature besides a human individual. Moreover, the object is not limited to living creatures, but rather may be of inanimate objects, such as, but not limited to, luggage, shipping containers, and/or the like.

Various embodiments provide methods and systems for forming or fabricating photodiode arrays, such as a front-lit through-via (FLTV) photodiode array having a diode junction formed at a via sidewall using selective doping. By practicing at least one embodiment, a dielectric layer is not added to the via as part of the through-silicon-via process. In various embodiments, the diode junction provides isolation between the via refill and the substrate. In addition, the diode junction formed at a via sidewall can reduce the coupling capacitance when compared to the isolation using a dielectric layer. Thus, various embodiments may provide a simplified and more reliable fabrication process.

Various embodiments provide a photodiode array with interconnects for use in a detector for imaging applications. For example, the photodiode array may be used with imaging systems, which are described herein in connection with computed tomography (CT) systems. However, the various embodiments may be implemented in connection with different types of imaging systems, such as positron emission tomography (PET) systems and nuclear medicine systems, such as single-photon emission computed tomography (SPECT) systems, as well as other types of imaging systems. Applications of imaging systems include medical applications, security applications, industrial inspection applications, and/or the like. Thus, although embodiments are described and illustrated herein with respect to a CT imaging system having detectors that detect x-rays, the various embodiments may be used with any other imaging modalities and may be used to detect, for example, any other type of electromagnetic energy. Moreover, the various embodiments described and/or illustrated herein are applicable with single slice and/or multi-slice configured systems.

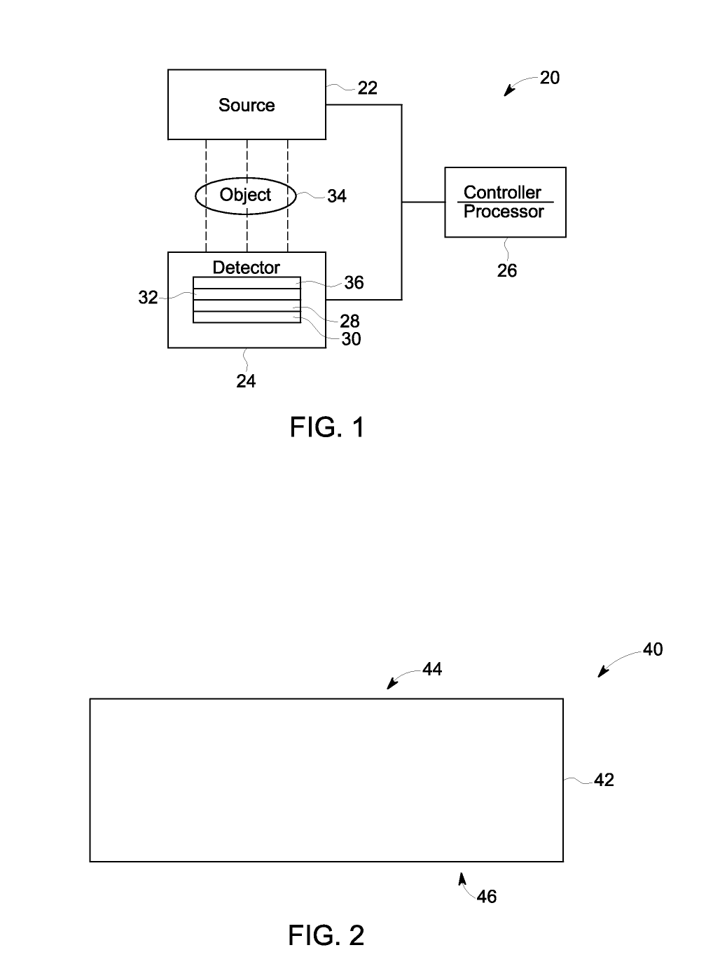

Referring now to FIG. 1, a detector having a photodiode array formed in accordance with various embodiments may be used in an imaging system 20 that includes a source 22 of electromagnetic energy, one or more detectors 24, and a controller/processor 26. The one or more detectors 24 also include a photosensor array, which in various embodiments is a photodiode array 28, and interconnections 30, which may connect to readout electronics (e.g., an analog-to-digital (A/D) converter to convert an analog signal current into a digital signal, or a combination of an amplifier and an A/D converter with the amplifier to convert an analog signal current into an analog voltage signal and the A/D converter to convert the voltage signal into a digital signal). In one embodiment, the photodiode array 28 and interconnections 30 in various embodiments are formed on two different sides of the same silicon wafer with electrical connection therebetween provided with conductive vias forming additional diode junctions to the photodiode array 28 as described in more detail herein. It should be noted that the readout electronics may form part of the detector 24 (which may be integrated, for example, with the silicon wafer forming the photodiode array 28). A post-object collimator 36 (e.g., a post-patient collimator) and a scintillator 32 is also provided as described in more detail below.

The controller/processor 26 may provide power and/or timing control signals to the source 22. The detector 24 senses energy emitted by the source 22 that has passed through an object 34 being imaged and the post-object collimator 36. In response thereto, the scintillator 32 converts the x-rays received into optical photons, and the photosensor array, in particular, the photodiode array 28 converts the optical photons into electrical current signals that represent the sensed energy. The interconnections 30 may be simple metal interconnection pads, or it may includes readout electronics, such as A/D converters, sample the analog current signals received from the photodiode array 28 and converts the data to digital signals. The controller/processor 26 performs subsequent processing and image reconstruction using the received digital signals. The reconstructed image may be stored and/or displayed by the controller/processor 26 and/or another device.

In various embodiments, the detector 24 is an indirect conversion detector wherein the scintillator 32 converts electromagnetic energy into visible (or near-UV) light photons, which are then converted to electrical analog signals by the photodiode array 28. The detector 24 may be any type of indirect conversion detector, such as, but not limited to, any detector with high density rare-earth ceramic scintillators.

One embodiment for fabricating the photodiode array 28 and interconnections 30 are illustrated in FIGS. 2 through 4. These Figures generally illustrate the steps for fabricating the photodiode array 28 and interconnections 30. It should be noted that the steps corresponding to each of FIGS. 2 through 4 may be performed sequentially. However, it should be noted that one or more of the steps may be performed concurrently or in a different order.

In particular, FIG. 2 illustrates a wafer used for the fabrication process. In one embodiment, a silicon wafer 40 is used, for example, a high resistivity bulk wafer. The wafer may be formed from any suitable semiconducting material. For example, the wafer may be formed from different materials, such as semiconductor materials including gallium nitride (GaN), with different dopants such as gallium, indium, aluminum, nitrogen, phosphorus or arsenic, or combinations thereof, among others.

In one embodiment, the silicon wafer 40 is a single layer wafer that includes a substrate 42 formed from a high resistivity N-type bulk material, such as an phosphorous doped material (e.g., having a resistivity greater than 800 ohm-cm or 1000 ohm-cm). For example, the substrate 42 in various embodiments may have a resistivity suitable for fabrication of the photodiode array 28, which may be a PIN diode array that operates at zero bias. The silicon wafer 40 may be formed from one or more layers of silicon material. In various embodiments, the structures described herein may be formed from process steps that include oxidation, ion implantation, diffusion, bonding, polishing and etching, among others.

In the illustrated embodiment, the substrate 42 is an N-doped silicon material (e.g., a layer doped with an N-type dopant such as phosphorus). However, it should be noted that in other embodiments the substrate 42 may be a P-doped silicon material (e.g., a layer doped with a P-type dopant such as boron). In various embodiments, the doping type of the substrate 42 may be N or N+, while in other embodiments the doping type may be P or P+.

It should be noted that in various embodiments the fabrication process may be used to form a back-connected two-dimensional (2D) tileable front-lit photodiode array, which may be embodied as the photodiode array 28. In these embodiments, one side 44 of the substrate 42 is an illumination side (referred to herein as the illumination side 44) and another side 46 of the substrate 42 is an interconnection side (referred to herein as the interconnection side 46).

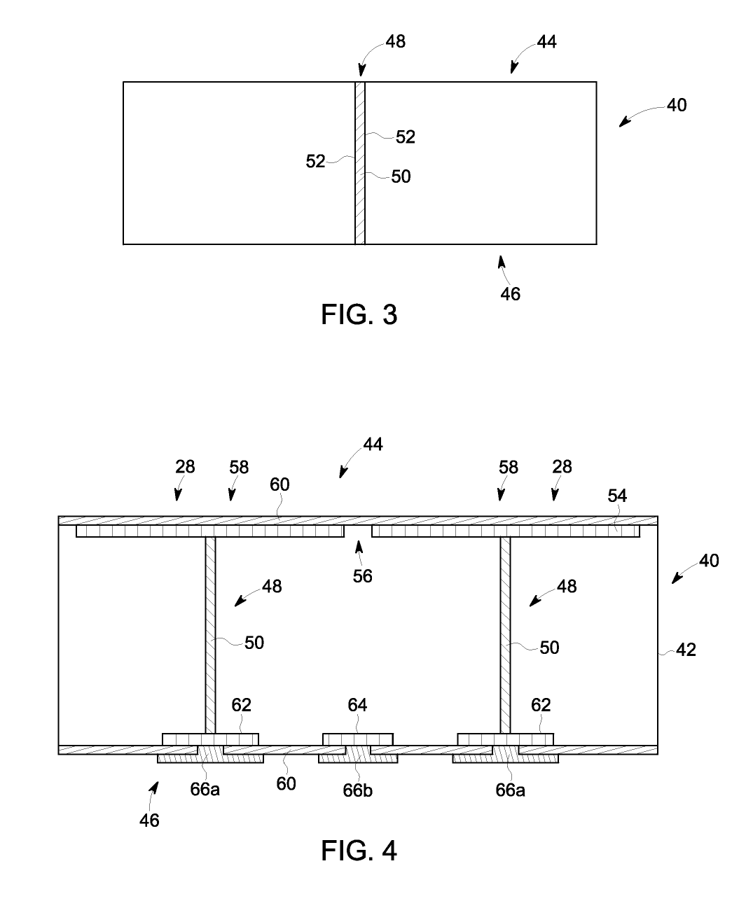

Referring now to FIG. 3, a through-silicon-via formation step is illustrated. In particular, a via 48, which in one embodiment is a hole extending from the light illumination side 44 to the interconnection side 46 is formed. Any suitable technique may be used to drill a hole through the wafer 40, such as using a plasma etch process. The hole forming the via 48 is used to define a conducive through silicon via, for example, a doped poly-Silicon (Si) refill. In particular, the via 48 is refilled with a doped poly material 50, which in one embodiment is a P++ poly via refill. In some embodiments, the P++ doping is 2-10 times higher than other P+ doping of other portions as described in more detail herein. Accordingly, the via 48 is formed and then a conductive refill is used to fill the via 48 with a doped poly material to form a conductive via. The refill process may be performed using any suitable via filling technique.

Thus, the via 48, which is a TSV, has a heavily doped poly-Si refill that defines the via conductor, wherein the interface between the via 48 and the substrate 42 forms a diode junction. In particular, side walls 52 of the via 48 having the doped poly material 50 form PN diode junctions with the substrate 42, as the doped poly material 50 and the substrate 42 have opposite doping types. Thus, as can be seen in the illustrated embodiment, there is no dielectric layer separating the doped poly material 50 from the substrate 42. The PN junction formed at the side walls 52 may also suppress dark leakage and coupling capacitance between the doped poly material 50 and the substrate 42 in various embodiments.

Thereafter, and as shown in FIG. 4, a plurality of photodiode arrays 28 are formed. Although the illustrated embodiment shows two photodiode arrays 28 formed on different portions (e.g., sides) of the illumination side 44, additional or fewer arrays may be formed and at different locations. For example, in one embodiment, a doped layer deposition (e.g., doped epi-layer deposition) and pattern etch is performed. This process forms the photodiode array 28, wherein the new deposition has the same doping type as the poly refill of the via 50, but may have a different doping concentration, which in various embodiments is a lower doping concentration. In another embodiment, a patterned ion implantation is performed on the light illumination side 44 having a same doping type as the poly refill, namely the doped poly material 50. For example, in one embodiment, a P+ doped layer 54 is generated by ion implantation on the light illumination side 44 of the wafer 40, which includes forming this layer overlapping with the via 48. The P+ doped layer 54 may be formed from any suitable process with patterns to define the pixelated array. For example, the P+ doped layer 54 may be formed by (i) a pre-diffusion process wherein the P+ doped layer 54 is driven into the high resistivity layer 44 by a high temperature or (ii) an epi-deposition process, wherein the P+ doped layer 54 is deposited by epitaxial growth.

The pattern of the P+ doped layer 54 defines gaps 56 between adjacent pixels. The P+ region of each pixel overlaps with a through-silicon—via 48 to make the photodiode array 28 electrically connected to the interconnection side 46 with the vias 48.

The various embodiments also include front and back side coatings, as well as a backside fabrication of interconnections. In particular, a silicon dioxide (SiO₂) layer 60 is formed on the light illumination side 44 and the interconnection side 46 of the wafer 40. For example, the SiO₂ layer 60 may be formed by a CVD deposition process at a relatively low temperature.

Additionally, interconnections are formed at the interconnection side 46, which may provide electrical connection for connection to, for example, electronics, such as the readout electronics. In some embodiments, the interconnections may be formed using a double-sided photolithography process that forms the interconnection when forming the active areas 58. However, in other embodiments, the interconnections may be formed in a separate process.

In particular, P+ doped regions 62 are formed at the interconnection side 46, which are formed over the vias 50. The P+ doped portions 62 may be formed from any suitable process, such as ion implantation or a diffusion process that drives the P+ doped portions 62 into the substrate 42. Additionally, an N+ doped region 64 is formed at the interconnection side 46, which may be formed similar to the P+ doped regions 62, and is formed between the P+ doped regions 62. The P+ doped regions 62 and the N+ doped region 64 are separated a distance along the interconnection side 46 within the substrate 42. It should be noted that the number of P+ doped regions 62 and the N+ doped region 64 are merely for illustration.

The interconnections (which may be embodied as the interconnections 30 shown in FIG. 1) are defined by the P+ doped regions 62 and the N+ doped region 64, along with metalizations 66a and 66b formed on the P+ doped regions 62 and the N+ doped region 64, respectively. The metalizations 66a and 66b in various embodiments define metal pads that may be connected to readout devices such as readout electronics electrically connected to the metalizations 66a and 66b, which may connect to other components (e.g., detector processing components).

Thus, the metalizations 66a and 66b may define electrical connectors to electrically connect the activate areas 58 through the vias 48 to the readout electronics or other components. The metalizations 66a and 66b may be, for example, interconnect bonding pads for conductive epoxy or a solder interconnection process in various embodiments. The metalizations 66a and 66b may be formed from any suitable material, such as metal, solder (e.g., solder bumps or balls) or conductive adhesive (e.g., epoxy plus a filler, such as nickel or graphite), among others.

It should be noted that the channel layout for the metalizations 66a and 66b, such as to connect to the readout electronics is generally in a pixelated pattern complementary to the arrangement of the photodiodes defined by the active areas 58, which may be arranged in a 2D array. However, it should be noted that the channel pitch may be smaller than the pitch of the array for the photodiodes, which provides spacing, such as to include passive components (e.g., power line filtering components) at the readout electronic device side. For example, the interconnection side 46 may have metal pads defined by the metalizations 66a and 66b that are slightly smaller than the diode pixel size to reduce or minimize capacitance. It also should be noted that the illumination side 44 in various embodiments has a diode pixel configuration (e.g., size and pattern arrangement) that reduces cross-talk and inter-pixel leakage.

Thus, a photosensor array and interconnect arrangement may be provided that includes the photodiode array 28 on one side of the silicon wafer 40 (with an additional diode junction formed between sidewalls 52 of the vias 48 and the substrate 42) and the interconnects defined by the metalizations 66a and 66b on a different side of the silicon wafer 40 with connection therebetween provided by conductive through silicon vias 48 (e.g., vias with heavily doped poly-Si refills). Using this arrangement, in various embodiments, a fully 2D tileable photodiode array chip for a CT detector module may be provided. For example, the photodiodes may detect light generated from the scintillator 32 (shown in FIG. 1) that is generated based on x-rays or gamma rays impinging on the scintillator 32. The light is converted to electrical current signals by the photodiodes 60, such as for use in CT imaging. It should be noted that in various embodiments the scintillator 32 is coupled to or positioned adjacent to the illumination side 44.

Thus, in various embodiments, the photodiodes of the photodiode arrays 28 correspond to detector pixels and one conductive via 48 is provided per pixel as shown. Thus, the active areas 58 define photodiodes of a photosensor array. The conductive vias 48 provide electrical connection between, for example, the active areas 58 and readout electronics connected to the metalizations 66a and 66b.

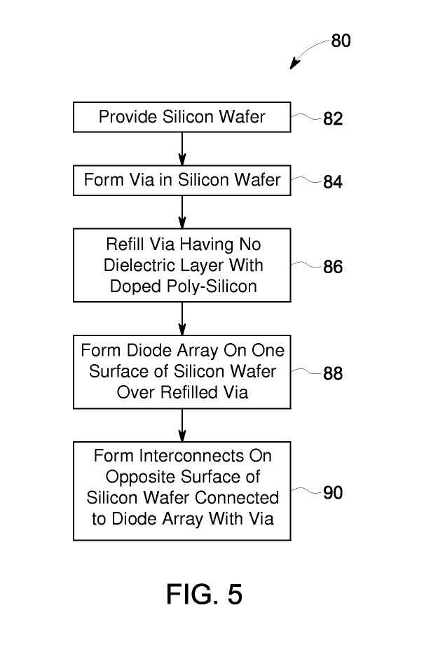

Various embodiments provide a method 80 as shown in FIG. 5 for forming a photodiode array and interconnects, for example, a detector module having an integrated photosensor array with connections for connecting to readout electronics. In particular, the method 80 includes providing a silicon wafer at 82, which in various embodiments is formed from a high resistivity bulk material. Thereafter, vias are formed in the silicon wafer at 84. For example, any suitable etching or drilling process may be used to form opening through the silicon wafer, such as from a top surface to a bottom surface.

The vias are then refilled at 86. The vias in various embodiments have no dielectric layer formed therein such that when the vias are refilled, a diode junction is formed between the walls of the refilled vias and the substrate. The vias are refilled in one embodiment with a doped poly-silicon having a doping type different than the substrate. For example, in one embodiment, the substrate is N-doped and the poly refill is P-doped. Thus, in various embodiments a PN diode junction is formed.

Thereafter, a diode array is formed on one surface of the wafer at 88. For example, a patterned ion implantation process as described herein may be used to form segregated active areas to define a photodiode array. The photodiode array may define a pixelated structure. The active areas are formed over the vias to provide electrical connection therewith to allow electrical signal flow.

Interconnects are also formed on the opposite surface of the wafer at 90. For example, metal pads are formed on the opposite surface over the vias such that the metal pads form interconnects electrically connected to the active areas. The interconnects allow connection to, for example, electronics. The formation of the diodes and the interconnects may be performed concurrently, for example, in a coordinated double-sided photolithography process. However, other suitable processes may be used.

Thus, various embodiments provide systems and methods for fabricating a front-lit through-via photodiode array with the diode junctions formed by an interface between refilled vias and the substrate. The silicon wafer with photosensor array and interconnects may be formed into 2D tileable silicon chips, such as through any suitable wafer dicing process. Thereafter the tileable silicon chips may be packaged to form a detector module.

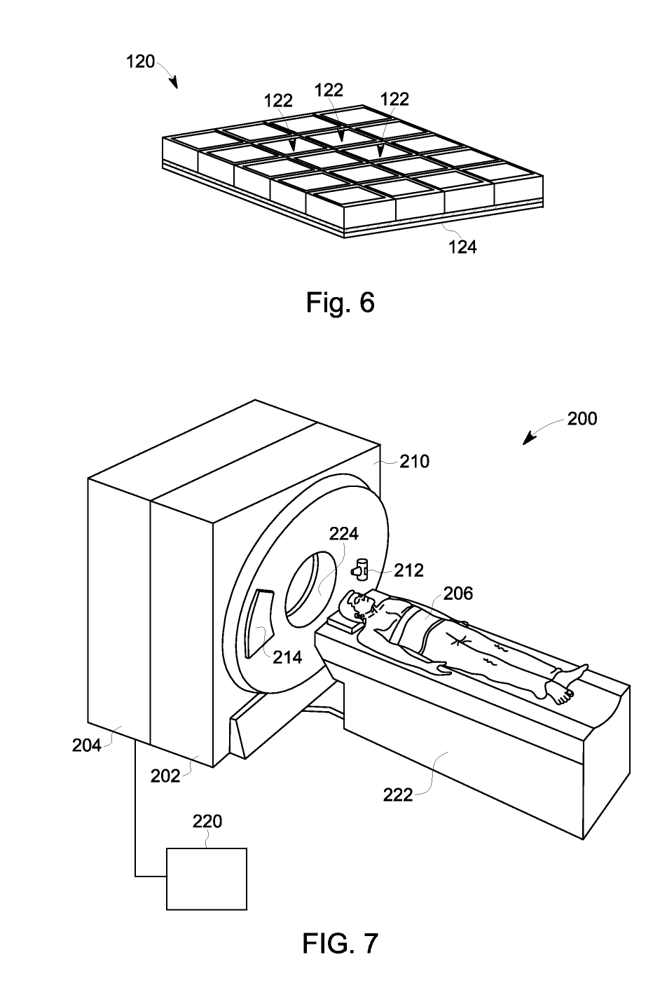

For example, as shown in FIG. 6, a plurality of sensor tiles 122 provided in accordance with various embodiments may form a detector module 120. The sensor tiles 122 may include a post-patient collimator, scintillator and the silicon chips with photosensor arrays, such as photodiode arrays and interconnects formed as described herein. For example, the detector module 120 may be configured as a CT detector module that includes a plurality, for example, twenty sensor tiles 122 arranged to form a rectangular array of five rows of four sensor tiles 122. The sensor tiles 122 are shown mounted on a printed circuit board 124 that may be coupled to processing and/or communication circuitry of a CT system. It should be noted that detector modules 120 having larger or smaller arrays of sensor tiles 122 may be provided. In operation, the x-ray signal detected by the sensor tiles 122 is generally determined from an integration of the total signal charges produced during a pre-defined period of time. However, other forms of signal sampling (e.g., readout of the signal corresponding to each individual x-ray) may be provided.

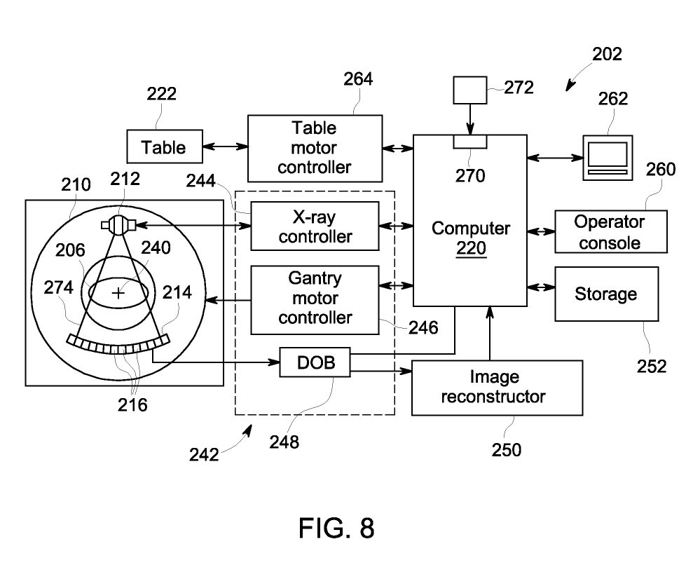

The various embodiments may be implemented in connection with different types of imaging systems. For example, FIG. 7 is a pictorial view of an exemplary imaging system 200 that is formed in accordance with various embodiments. FIG. 8 is a block schematic diagram of a portion of the imaging system 200 shown in FIG. 7. Although various embodiments are described in the context of an exemplary dual modality imaging system that includes a computed tomography (CT) imaging system and a positron emission tomography (PET) imaging system, it should be understood that other imaging systems capable of performing the functions described herein are contemplated as being used, including single modality imaging systems.

The multi-modality imaging system 200 is illustrated, and includes a CT imaging system 202 and a PET imaging system 204. The imaging system 200 allows for multiple scans in different modalities to facilitate an increased diagnostic capability over single modality systems. In one embodiment, the exemplary multi-modality imaging system 200 is a CT/PET imaging system 200. Optionally, modalities other than CT and PET are employed with the imaging system 200. For example, the imaging system 200 may be a standalone CT imaging system, a standalone PET imaging system, a magnetic resonance imaging (MRI) system, an ultrasound imaging system, an x-ray imaging system, and/or a single photon emission computed tomography (SPECT) imaging system, interventional C-Arm tomography, CT systems for a dedicated purpose such as extremity or breast scanning, and combinations thereof, among others.

The CT imaging system 202 includes a rotation gantry 210 that has an x-ray source 212 that projects a beam of x-rays toward a detector array 214 on the opposite side of the gantry 210. The detector array 214 includes a plurality of detector elements 216 that are arranged in rows and channels that together sense the projected x-rays that pass through an object, such as the subject 206, and which may be configured as multiple detector modules according to one or more embodiments described herein. The imaging system 200 also includes a computer 220 that receives the projection data from the detector array 214 and processes the projection data to reconstruct an image of the subject 206. In operation, operator supplied commands and parameters are used by the computer 220 to provide control signals and information to reposition a motorized table 222. More specifically, the motorized table 222 is utilized to move the subject 206 into and out of the gantry 210. Particularly, the table 222 moves at least a portion of the subject 206 through a gantry opening 224 that extends through the gantry 210.

As discussed above, the detector 214 includes a plurality of detector elements 216. Each detector element 216 produces an electrical signal, or output, that represents the intensity of an impinging x-ray beam and hence allows estimation of the attenuation of the beam as it passes through the subject 206. During a scan to acquire the x-ray projection data, the gantry 210 and the components mounted thereon rotate about a center of rotation 240. The multislice detector array 214 includes a plurality of parallel detector rows of detector elements 216 such that projection data corresponding to a plurality of slices can be acquired simultaneously during a scan.

Rotation of the gantry 210 and the operation of the x-ray source 212 are governed by a control mechanism 242. The control mechanism 242 includes an x-ray controller 244 that provides power and timing signals to the x-ray source 212 and a gantry motor controller 246 that controls the rotational speed and position of the gantry 210. A digital data buffer (DDB) 248 in the control mechanism 242 receives and store the digital data from the detector 214 for subsequent process. An image reconstructor 250 receives the sampled and digitized x-ray data from the DDB 248 and performs high-speed image reconstruction. The reconstructed images are input to the computer 220 that stores the image in a storage device 252. Optionally, the computer 220 may receive the sampled and digitized x-ray data from the DDB 248. The computer 220 also receives commands and scanning parameters from an operator via a console 260 that has a keyboard. An associated visual display unit 262 allows the operator to observe the reconstructed image and other data from computer.

The operator supplied commands and parameters are used by the computer 220 to provide control signals and information to the DDB 248, the x-ray controller 244 and the gantry motor controller 246. In addition, the computer 220 operates a table motor controller 264 that controls the motorized table 222 to position the subject 206 in the gantry 210. Particularly, the table 222 moves at least a portion of the subject 206 through the gantry opening 224 as shown in FIGS. 7 and 8.

Referring again to FIG. 8, in one embodiment, the computer 220 includes a device 270, for example, a floppy disk drive, CD-ROM drive, DVD drive, magnetic optical disk (MOD) device, or any other digital device including a network connecting device such as an Ethernet device for reading instructions and/or data from a computer-readable medium 272, such as a floppy disk, a CD-ROM, a DVD or an other digital source such as a network or the Internet, as well as yet to be developed digital means. In another embodiment, the computer 220 executes instructions stored in firmware (not shown). The computer 220 is programmed to perform functions described herein, and as used herein, the term computer is not limited to just those integrated circuits referred to in the art as computers, but broadly refers to computers, processors, microcontrollers, microcomputers, programmable logic controllers, application specific integrated circuits, and other programmable circuits, and these terms are used interchangeably herein.

In the exemplary embodiment, the x-ray source 212 and the detector array 214 are rotated with the gantry 210 within the imaging plane and around the subject 206 to be imaged such that the angle at which an x-ray beam 274 intersects the subject 206 constantly changes. A group of x-ray attenuation measurements, i.e., projection data, from the detector array 214 at one gantry angle is referred to as a “view”. A “scan” of the subject 206 comprises a set of views made at different gantry angles, or view angles, during one revolution of the x-ray source 212 and the detector 214. In a CT scan, the projection data is processed to reconstruct an image that corresponds to a two dimensional slice taken through the subject 206.

Exemplary embodiments of a multi-modality imaging system are described above in detail. The multi-modality imaging system components illustrated are not limited to the specific embodiments described herein, but rather, components of each multi-modality imaging system may be utilized independently and separately from other components described herein. For example, the multi-modality imaging system components described above may also be used in combination with other imaging systems.

The various embodiments and/or components, for example, the modules, or components and controllers therein, also may be implemented as part of one or more computers or processors. The computer or processor may include a computing device, an input device, a display unit and an interface, for example, for accessing the Internet. The computer or processor may include a microprocessor. The microprocessor may be connected to a communication bus. The computer or processor may also include a memory. The memory may include Random Access Memory (RAM) and Read Only Memory (ROM). The computer or processor further may include a storage device, which may be a hard disk drive or a removable storage drive such as a floppy disk drive, optical disk drive, and the like. The storage device may also be other similar means for loading computer programs or other instructions into the computer or processor.

As used herein, the term “computer” or “module” may include any processor-based or microprocessor-based system including systems using microcontrollers, Reduced Instruction Set Computers (RISC), ASICs, logic circuits, and any other circuit or processor capable of executing the functions described herein. The above examples are exemplary only, and are thus not intended to limit in any way the definition and/or meaning of the term “computer”.

The computer or processor executes a set of instructions that are stored in one or more storage elements, in order to process input data. The storage elements may also store data or other information as desired or needed. The storage element may be in the form of an information source or a physical memory element within a processing machine.

The set of instructions may include various commands that instruct the computer or processor as a processing machine to perform specific operations such as the methods and processes of the various embodiments. The set of instructions may be in the form of a software program, which may form part of a tangible non-transitory computer readable medium or media. The software may be in various forms such as system software or application software. Further, the software may be in the form of a collection of separate programs or modules, a program module within a larger program or a portion of a program module. The software also may include modular programming in the form of object-oriented programming. The processing of input data by the processing machine may be in response to operator commands, or in response to results of previous processing, or in response to a request made by another processing machine.

As used herein, the terms “software” and “firmware” are interchangeable, and include any computer program stored in memory for execution by a computer, including RAM memory, ROM memory, EPROM memory, EEPROM memory, and non-volatile RAM (NVRAM) memory. The above memory types are exemplary only, and are thus not limiting as to the types of memory usable for storage of a computer program.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the various embodiments without departing from their scope. While the dimensions and types of materials described herein are intended to define the parameters of the various embodiments, the embodiments are by no means limiting and are exemplary embodiments. Many other embodiments will be apparent to those of skill in the art upon reviewing the above description. The scope of the various embodiments should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

This written description uses examples to disclose the various embodiments, including the best mode, and also to enable any person skilled in the art to practice the various embodiments, including making and using any devices or systems and performing any incorporated methods. The patentable scope of the various embodiments is defined by the claims, and may include other examples that occur to those skilled in the art. Such other examples are intended to be within the scope of the claims if the examples have structural elements that do not differ from the literal language of the claims, or if the examples include equivalent structural elements with insubstantial differences from the literal languages of the claims.

What is claimed is:

1. A photodiode array comprising:
a silicon wafer having a first surface and an opposite second surface;
a plurality of refilled conductive vias through the silicon wafer, the refilled conductive vias having a doping type different than the doping type of the substrate, wherein an interface between the refilled conductive vias and the substrate form diode junctions; and
a patterned doped layer on the first surface overlapping with the refilled conductive vias, the patterned doped layer having the same doping type as the refilled conductive vias and form an array of photodiodes.

2. The photodiode array of claim 1, wherein the refilled conductive vias comprise a poly-silicon material without a dielectric layer between the refilled conductive vias and the substrate.

3. The photodiode array of claim 1, wherein the diode junctions are formed between sidewalls of the refilled conductive vias and the substrate.

4. The photodiode array of claim 1, wherein the silicon wafer comprises a high resistivity bulk silicon material.

5. The photodiode array of claim 1, wherein the refilled conductive vias comprise a doped poly-silicon refill having a doping concentration higher than the doped layer on the first surface.

6. The photodiode array of claim 1, further comprising a dielectric layer formed on the first and second surfaces of the silicon wafer, the dielectric layer comprising silicon dioxide (SiO₂).

7. The photodiode array of claim 1, further comprising patterned doped regions at the second surface of the silicon wafer having metalizations formed thereon to define interconnects.

8. The photodiode array of claim 7, wherein at least one of the patterned doped regions is an N-type doped region and at least one of the patterned doped regions is a P-type doped region.

9. The photodiode array of claim 7, wherein a pitch of the metalizations is less than a pitch of a pixel pattern of the array of photodiodes.

10. A detector comprising:
a silicon wafer having a first surface and an opposite second surface;
a plurality of refilled conductive vias through the silicon wafer without a dielectric layer, the refilled conductive vias having a doping type different than the doping type of the substrate, wherein an interface between the refilled conductive vias and the substrate forming diode junctions;
a plurality of photodiodes formed at the first surface; and
interconnects formed on the opposite second surface by metalizations, wherein the plurality of photodiodes and the interconnects are electrically connected by the plurality of refilled conductive vias.

11. The detector of claim 10, wherein the refilled conductive vias comprise a poly-silicon material.

12. The detector of claim 10, wherein the diode junctions are formed between sidewalls of the refilled conductive vias and the substrate.

13. The detector of claim 10, wherein the silicon wafer comprises a high resistivity bulk silicon material.

14. The detector of claim 10, wherein the refilled conductive vias comprise a doped poly-silicon refill having a doping concentration higher than a doped layer on the first surface forming the plurality of photodiodes.

15. The detector of claim 14, wherein the refilled conductive vias have a same doping type as the doped layer on the first surface.

16. The detector of claim 10, further comprising a dielectric layer formed on the first and second surfaces of the silicon wafer, the dielectric layer comprising silicon dioxide (SiO₂).

17. The detector of claim 10, wherein a pitch of the metalizations is less than a pitch of a pixel pattern of the array of photodiodes.

18. A method for fabricating a photodiode array, the method comprising:
forming vias through a silicon wafer;
refilling the vias with a doped poly-silicon without a dielectric layer, the doping for the refilled vias different than the doping type of the silicon wafer; and
forming a patterned doped layer on a surface of the silicon wafer over the plurality of vias, wherein patterned doped layer form patterned doped regions defining active areas of photodiode pixels and diode junctions are formed at an interface between the vias and the substrate.

19. The method of claim 18, further comprising forming metalizations on a surface of the silicon wafer opposite the surface with the patterned doped regions, the metalizations defining interconnects.

20. The method of claim 18, wherein the refilled vias have a same doping type as the patterned doped layer on the first surface
